(19) United States
(12) Patent Application Publication
(10) Pub. No.: US 2006/0131648 A1
(43) Pub. Date: Jun. 22, 2006

(54) Ultra thin film SOI MOSFET having recessed source/drain structure and method of fabricating the same

(75) Inventors: Chang Geun Ahn, Daejeon-city (KR); Wonju Cho, Daejeon-city (KR); Kiju Im, Daejeon-city (KR); Jong Heon Yang, Daejeon-city (KR); In Bok Baek, Daejeon-city (KR); Seong Jae Lee, Daejeon-city (KR); Sung Kweon Baek, Daejeon-city (KR)

Correspondence Address: MAYER, BROWN, ROWE & MAW LLP, 1909 K STREET, N.W., WASHINGTON, DC, 20006, US

(73) Assignee: ELECTRONICS AND TELECOMMUNICATIONS RESEARCH INSTITUTE

(21) Appl. No.: 11/137,396

(22) Filed: May 26, 2005

(30) Foreign Application Priority Data
Dec. 17, 2004 (KR) 10-2004-0108155

(51) Int. Cl. H01L 27/12

(52) U.S. Cl. 257/347

(57) ABSTRACT

There are provided an ultra thin film silicon on insulator (SOI) metal oxide semiconductor field effect transistor (MOSFET) having a recessed source/drain structure, and a method of fabricating the same. The ultra thin film SOI MOS transistor includes a semiconductor substrate; a buried insulating layer disposed on the semiconductor substrate, and formed recessed except for a center portion thereof; an ultra thin film single crystalline silicon layer pattern disposed on the recessed buried insulating layer; a gate stack disposed on the ultra thin film single crystalline silicon layer pattern, and including a gate insulating layer pattern and a gate conductive layer pattern, which are sequentially stacked; a gate spacer layer disposed on sidewalls of the gate stack; and a recessed source/drain region disposed on the recessed buried insulating layer, and formed to overlap a bottom surface portion of the ultra thin film single crystalline silicon layer pattern, which does not overlap the center portion of the recessed buried insulating layer.

### CROSS-REFERENCE TO RELATED PATENT APPLICATION

This application claims the benefit of Korean Patent Application No. 10-2004-0108155, filed on Dec. 17, 2004, in the Korean Intellectual Property Office, the disclosure of which is incorporated herein in its entirety by reference.

### BACKGROUND OF THE INVENTION

1. Field of the Invention

The present invention relates to a method of fabricating a semiconductor device, and an ultra thin film silicon on insulator (SOI) metal oxide semiconductor field effect transistor (MOSFET) having a recessed source/drain structure, and a method of fabricating the same.

2. Description of the Related Art

Recently, with the increase of demand for a low power consumption, a high integration, an ultra high speed device characteristics of semiconductor devices, and the like, it is also required that a size of a MOS transistor employed in various semiconductor devices be reduced. In specific, it is required that a channel length of a MOS transistor, a depth of a source/drain junction, and a thickness of a gate insulating layer be reduced. However, as widely known, when the channel length is excessively reduced, there occurs a short channel effect. Further, even in the device having a same size, a high performance of the device characteristics must be implemented through an increase of a drive current and a reduction of a leakage current.

However, with the device size being reduced down to deep-submicron of approximately 100 nm or below, typical short channel effects become more serious problems. For example, when phenomenons such as punch-through, drain induced barrier lowering (DIBL), and gate induced drain leakage current (GIDL), and the like, a roll-off characteristic of a threshold voltage occurs, and an on/off ratio of a drain current is reduced.

In order to alleviate the short channel effect as above, it is necessary to reduce a depth of a source/drain junction. However, there is a limitation to form the ultra shallow junction by using a high energy ion implantation method or a high temperature diffusion process, which is now widely employed. Various methods have been proposed in order to solve the problems. One of the methods involves a low energy ion implantation and a spike rapid thermal processing, in which an ion implantation energy is decreased to a minimum and then, a thermal processing is performed in short time. Another one of the methods is to prevent a channel leakage current flowing below a channel region being little influential in the control of a gate region in a bulk silicon device. The method can be easily implemented using an SOI substrate. The use of the SOI substrate also provides a merit of easily forming the ultra shallow junction in addition to the effect of preventing a channel leakage current.

However, the methods both have unavoidable problems. That is, when a junction is very shallow, or a thin film is very thin in thickness, a resistance of a source/drain region is increased that much. As a result, it occurs a serious reduction of a drive current, one of the important elements in scaling of devices. Furthermore, even in an elevated source/drain SOI MOSFET having an elevated source/drain region formed in order to reduce a high resistance in a source/drain region when an ultra thin film SOI substrate is used, there still occurs a problem of a high resistance in a source/drain extension region for a lightly doped drain (LDD) structure. The problem becomes more serious with an integration of a device being increased.

### SUMMARY OF THE INVENTION

The present invention provides an ultra thin film silicon on insulator (SOI) metal oxide semiconductor field effect transistor (MOSFET) having a recessed source/drain structure being capable of suppressing a resistance increase of a source/drain region, thereby preventing a reduction of a drive current due to a resistance increase of the source/drain region.

The present invention also provides a method of fabricating an ultra thin film SOI MOSFET having a recessed source/drain structure.

According to an aspect of the present invention, there is provided an ultra thin film SOI MOSFET including a semiconductor substrate; a buried insulating layer disposed on the semiconductor substrate, and formed recessed except for a center portion thereof; an ultra thin film single crystalline silicon layer pattern disposed on the recessed buried insulating layer; a gate stack disposed on the ultra thin film single crystalline silicon layer pattern, and including a gate insulating layer pattern and a gate conductive layer pattern, which are sequentially stacked; a gate spacer layer disposed on sidewalls of the gate stack; and a recessed source/drain region disposed on the recessed buried insulating layer, and formed to overlap a bottom surface portion of the ultra thin film single crystalline silicon layer pattern, which does not overlap the center portion of the recessed buried insulating layer.

The semiconductor substrate, the recessed buried insulating layer, and the ultra thin film single crystalline silicon layer pattern may constitute an SOI substrate. The recessed buried insulating layer may be an oxide layer. End portions of the ultra thin film single crystalline silicon layer pattern may be formed in a direction normal to sidewalls of the gate spacer layer. The recessed source/drain region may be a polycrystalline silicon layer doped with high concentration impurities.

The present invention may further include a hard mask layer pattern disposed on the gate conductive layer pattern. In this case, the hard mask layer pattern may have a structure in which a silicon oxide layer pattern and a silicon nitride layer pattern are sequentially stacked. Further, the present invention may further include a metal silicide layer disposed on an exposed surface of the recessed source/drain region.

According to another aspect of the present invention, there is provided a method of fabricating an ultra thin film SOI MOS transistor including preparing an SOI substrate formed by sequentially stacking a semiconductor substrate, a buried insulating layer, and a single crystalline silicon layer; removing the single crystalline silicon layer by a predetermined thickness, thereby forming an ultra thin film single crystalline silicon layer; forming a gate stack on the ultra thin film single crystalline silicon layer; forming a gate spacer layer on sidewalls of the gate stack; removing an exposed portion of the ultra thin film single crystalline silicon layer, being not covered by the gate stack and the gate spacer layer, thereby forming an ultra thin film single crystalline silicon layer pattern disposed below the gate stack and the gate spacer layer; partially removing the buried insulating layer, thereby forming a recessed buried insulating layer, which is recessed at a rest portion except for a center portion below the ultra thin film single crystalline silicon layer pattern; and forming a source/drain region on the recessed buried insulating layer.

The buried insulating layer may be an oxide layer. The operation of forming the ultra thin film single crystalline silicon layer may include performing an oxidation process on the single crystalline silicon layer; and removing an oxide layer formed in an upper portion of the single crystalline silicon layer by the oxidation process. In this case, the oxidation process and the oxide layer removing process may be performed using a dry oxidation process and a wet etch process respectively. The prevent invention may further include channel-doping for the ultra thin film single crystalline silicon layer to control a threshold voltage and reduce a short channel effect.

The gate stack may be formed to have a structure of a gate insulating layer pattern and a gate conductive layer pattern, which are sequentially stacked. In this case, the gate stack may further include a hard mask layer pattern formed on the gate conductive layer pattern. The gate insulating layer pattern may be formed of a silicon thermal oxide layer or a high-k insulating layer, the gate conductive layer pattern may be formed of a polycrystalline silicon layer or a metal layer, and the hard mask layer pattern may be formed of a silicon oxide layer and a silicon nitride layer.

The operation of forming the gate spacer layer may include forming an insulating layer for a gate spacer layer on the overall surface of the resultant structure having the gate stack; and performing an anisotropic etch process on the insulating layer, thereby exposing an upper surface of the gate stack and a portion of the surface of the thin film single crystalline silicon layer.

In this case, the insulating layer for the gate spacer layer may be formed using a silicon nitride layer. The thin film single crystalline silicon layer pattern may be formed performing an anisotropic etch process on the thin film single crystalline silicon layer exposed by the gate stack and the gate spacer layer. The recessed buried insulating layer may be formed by performing a wet etch process on the buried insulating layer. In this case, the wet etch process may be performed using a diluted HF solution or a BOE solution as an etch solution.

The operation of forming the source/drain region may include forming a conductive layer on an overall surface of the resultant structure having the recessed buried insulating layer; forming an etch mask layer pattern on the conductive layer to expose an upper surface of the gate stack and the conductive layer around the gate stack; performing an etch process using the etch mask layer pattern as an etch mask, thereby removing the exposed portion of the conductive layer; and removing the etch mask layer pattern.

In this case, the conductive layer may be formed of a polycrystalline silicon layer doped with high concentration impurities. The operation of forming the polycrystalline silicon layer may be performed using a chemical vapor deposition (CVD) method, a physical vapor deposition (PVD) method, or an atomic layer deposition (ALD) method. The conductive layer may be formed of an amorphous silicon layer or a single crystalline silicon layer formed by an epitaxy growth method. The etch mask layer pattern may be formed of a floating oxide layer. In this case, the operation of removing the etch mask layer pattern may be performed using a wet etch process on the floating oxide layer. The operation of removing the exposed portion of the conductive layer by the etch process using the etch mask layer pattern as an etch mask may be performed by an anisotropic etch process. The present invention may further include forming a metal silicide layer on the source/drain region.

### BRIEF DESCRIPTION OF THE DRAWINGS

The above and other features and advantages of the present invention will become more apparent by describing in detail exemplary embodiments thereof with reference to the attached drawings in which:

FIGS. 1 through 12 are sectional views illustrating a method of fabricating a thin film silicon on insulator (SOI) metal oxide semiconductor field effect transistor (MOSFET) according to the present invention; and

FIG. 13 is a sectional view illustrating an ultra thin film SOI MOSFET according to the present invention.

### DETAILED DESCRIPTION OF THE INVENTION

The present invention will now be described more fully hereinafter with reference to the accompanying drawings, in which preferred embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art. Like numbers refer to like elements throughout the specification.

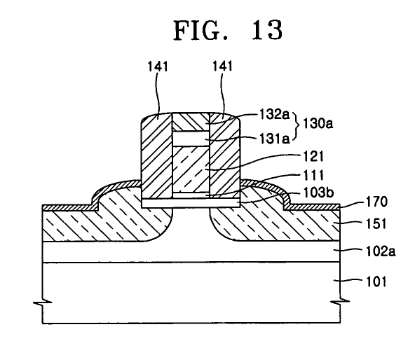

FIG. 13 is a sectional view illustrating a thin film silicon on insulator (SOI) metal oxide semiconductor field effect transistor (MOSFET) according to the present invention.

Referring to FIG. 13, in the ultra thin film SOI MOSFET of the present invention, a recessed buried oxide layer 102a is disposed on a single crystalline substrate 101. The recessed buried oxide layer 102a is structured being recessed at its rest portion except for its center portion. An ultra thin film single crystalline silicon layer pattern 103b is disposed at the center portion of the recessed buried oxide layer 102a. The ultra thin film single crystalline silicon layer pattern 103b is disposed to partially overlap the recessed portion of the recessed buried oxide layer 102a as well as the center portion of the recessed buried oxide layer 102a.

A gate stack is formed on the ultra thin film single crystalline silicon layer pattern 103b by sequentially stacking a gate insulating layer pattern 111, a gate conductive layer pattern 121, and a hard mask layer pattern 130a. The hard mask layer pattern 130a is composed of two layers including a lower silicon oxide layer pattern 131a and an upper silicon nitride layer pattern 132a. Alternatively, the hard mask layer pattern 130a may have a structure of a single layer or three layers or more. The gate stack is vertically disposed relative to the center portion of the recessed buried oxide layer 102a. Gate spacer layers 141 are disposed on the sidewalls of the gate stack respectively.

Source/drain regions 151 are disposed on the recessed portions of the recessed buried oxide layer 102a respectively. The recessed structure of the source/drain region 151 is composed of a polycrystalline silicon layer doped with high concentration impurities. The source/drain region 151 having the recessed structure contacts the bottom surface of the ultra thin film single crystalline silicon layer pattern 103b, particularly the bottom surface portion horizontally protruded from the center portion of the recessed buried oxide layer 102a. A metal silicide layer 170 is disposed on the recessed source/drain regions 151.

The ultra thin film SOI MOSFET having the recessed source/drain regions structured as above can suppress a short channel effect and reduce the resistance of the source/drain regions. That is, an inversion layer generated when a bias above a threshold voltage is applied to the gate conductive layer pattern 121 or a channel is formed inside the ultra thin film single crystalline silicon layer pattern 103b below the gate insulating layer 111. The inversion layer or the channel cannot be formed deeper because of the presence of the center portion of the recessed buried oxide layer 102a even though the recessed source/drain regions 151 is great in thickness. Thus, the short channel effect can be suppressed. Therefore, since the thickness of the recessed source/drain regions 151 does not affect the depth of the inversion layer or the channel, the thickness of the recessed source/drain regions 151 doped with high concentration impurities can be formed sufficiently great, thereby reducing the resistance of the recessed source/drain regions 151.

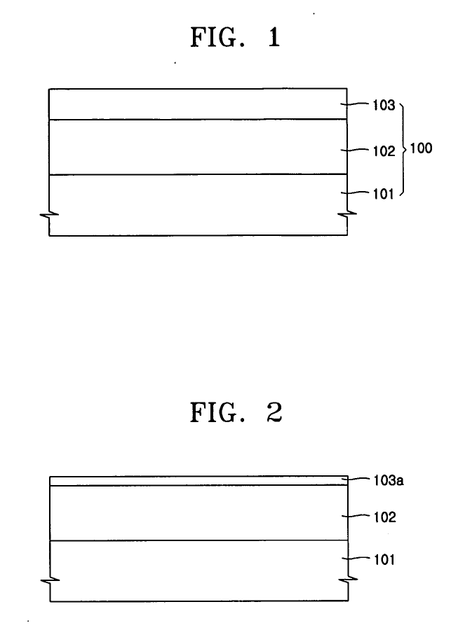

Hereinafter, a method of fabricating the SOI MOSFET structured as above will be described in detail with reference to FIGS. 1 through 12 along with FIG. 13.

FIGS. 1 and 2 are sectional views illustrating the process of forming a ultra thin film single crystalline silicon layer in the method of fabricating the SOI MOSFET according to the present invention.

As shown in FIG. 1, an SOI substrate 100 is prepared by sequentially stacking a buried oxide layer 102 as a buried insulating layer and a single crystalline silicon layer 103 on a semiconductor substrate, for example, a silicon substrate 101. As shown in FIG. 2, the single crystalline silicon layer 103 is partially removed by a predetermined thickness, thereby forming an ultra thin film single crystalline silicon layer 103a. The ultra thin film single crystalline silicon layer 103a may be formed by performing a dry oxidation process and a wet etch process. That is, the dry oxidation process is first performed so as to oxidize the upper portion of the single crystalline silicon layer 103 and then, the wet etch process is performed so as to remove the upper oxide layer of the single crystalline silicon layer 103, thereby providing the ultra thin film single crystalline silicon layer 103a. The ultra thin film single crystalline silicon layer 103a may be an n-type or p-type. Further, a channel doping process may be performed in order to control a threshold voltage and reduce a short channel effect.

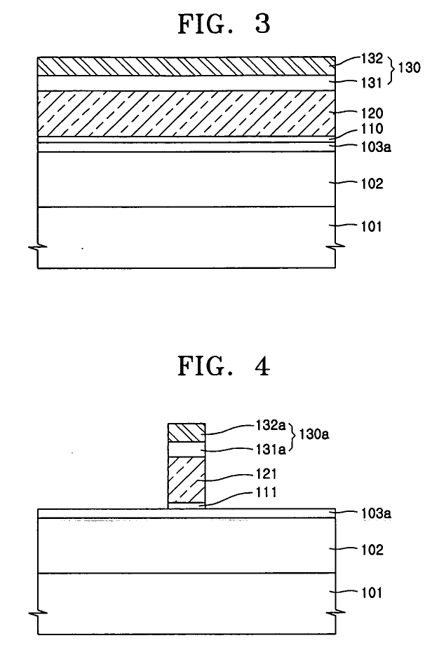

FIGS. 3 and 4 are sectional views illustrating a process of forming a gate stack in the method of fabricating the SOI MOSFET according to the present invention.

As shown in FIG. 3, a gate insulating layer 110 and a gate conductive layer 120 are sequentially formed on the ultra thin film single crystalline silicon layer 103a. Then, a hard mask layer 130 is formed on the gate conductive layer 120. The gate insulating layer 110 may be formed of a silicon oxide layer. In cases, the gate insulating layer 110 may be formed of a high-k insulating layer. The gate conductive layer 120 may be formed of a polycrystalline silicon layer doped with high concentration impurities by using a chemical vapor deposition (CVD) method or physical vapor deposition (PVD) method. In cases, the doping of high concentration impurities may be performed separately later. The impurities may use n-type or p-type impurities such as phosphorus, boron, arsenic, and the like. The gate conductive layer 120 may be formed of a metal layer. The hard mask layer 130 is formed by sequentially stacking a silicon oxide layer 131 and a silicon nitride layer 132. The silicon oxide layer 131 and the silicon nitride layer 132 may be formed using a CVD method.

As shown in FIG. 4, a gate stack is formed by sequentially stacking a gate insulating layer pattern 111, a gate conductive layer pattern 121, and a hard mask layer pattern 130a. The hard mask layer pattern 130a includes a silicon oxide layer pattern 131a and a silicon nitride layer pattern 132a, which are sequentially stacked. In order to form the gate stack, a photoresist layer pattern or an electron beam resist layer pattern (not shown) as a mask layer pattern is formed on the hard mask layer 130. The photoresist layer pattern or the electron beam resist layer pattern covers the portion of the hard mask layer 130 where the gate stack will be formed.

Then, an etch process is performed using the photoresist layer pattern or the electron beam resist layer pattern as an etch mask, thereby sequentially removing the exposed portions of the hard mask layer 130, the gate conductive layer 120, and the gate insulating layer 110. Then, the photoresist layer pattern or the electron beam resist layer pattern is removed, thereby forming the gate stack. The etch process uses an anisotropic dry etch process such as reactive ion etching (RIE). At this time, the thin film single crystalline silicon layer 103a may be lost by the etch depending on the kind of an etch gas to be used. For the reason, an etch gas having a high etch selectivity with respect to the gate insulating layer 110 may be used during the etch of the gate conductive layer 120 in order to avoid the problem. When the gate stack is formed by the method as above, the surface of the thin film single crystalline silicon layer 103a except for the surface portion covered by the gate stack is partially exposed.

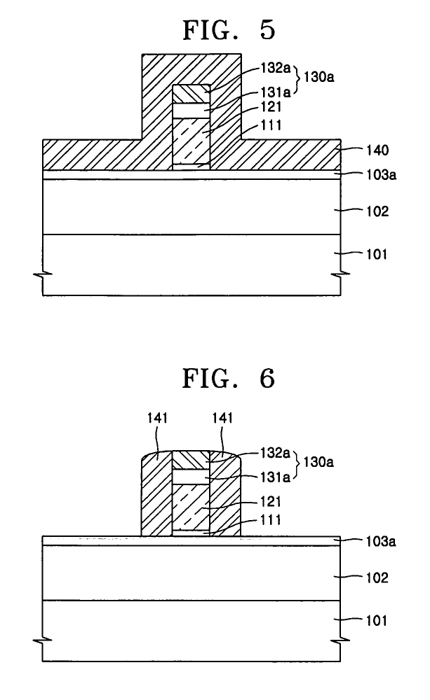

FIGS. 5 and 6 are sectional views illustrating a process of forming a gate spacer layer in the method of fabricating the SOI MOSFET according to the present invention.

As shown in FIG. 5, an insulating layer 140 to form a gate spacer layer is formed on the overall surface of the resultant structure having the gate stack (resultant structure of FIG. 4). The insulating layer 140 may be formed of a silicon nitride layer. By the thickness of the insulating layer 140, in specific, thickness of the gate spacer layer which will be remained on the sidewalls of the gate stack after an etch process performed on the insulating layer 140, as the length of a source/drain extension portion is defined, and as the thickness affects an etch time to form the recessed buried oxide layer in a subsequent process, the thickness of the insulating layer 140 is determined considering the above relations.

As shown in FIG. 6, an etch process is performed on the insulating layer 140, thereby forming a gate spacer layer 141 disposed on the sidewalls of the gate stack and exposing a portion of the surface of the thin film single crystalline silicon layer 103a. The etch process for forming the gate spacer layer 141 may be performed using an anisotropic dry etch process such as RIE. The gate spacer layer 141 formed as above reduces a parasitic capacitance by the overlapping of the source region and the gate, and suppresses a short channel effect by an excessive diffusion at the sides.

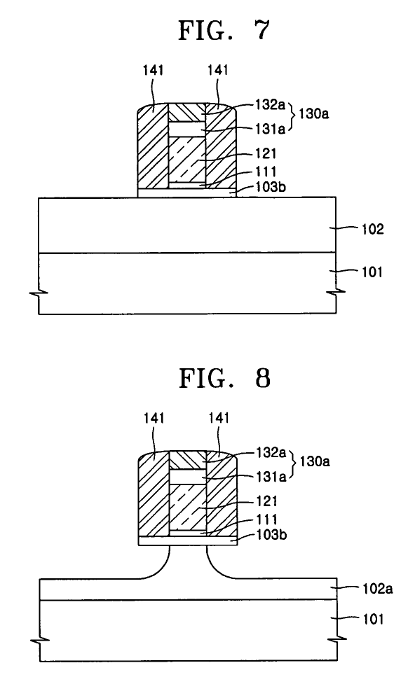

FIGS. 7 and 8 are sectional views illustrating a process of forming a recessed buried oxide layer in the method of fabricating an SOI MOSFET according to the present invention.

As shown in FIG. 7, the exposed portion of the thin film single crystalline silicon layer 103a exposed by the gate stack and the gate spacer layer 141 is removed, thereby forming an ultra thin film single crystalline silicon layer pattern 103b. When the ultra thin film single crystalline silicon layer pattern 103b, the surface of the rest region of the buried insulating layer 102 except for the channel region and the source/drain diffusion region is exposed.

Then, as shown in FIG. 8, a portion of the buried insulating layer 102 (FIG. 7) is removed, thereby forming a recessed buried insulating layer 102a. The recessed buried insulating layer 102a has a recessed structure at the rest portion except for its center portion. In order to form the recessed buried insulating layer 102a as above, a wet etch process is performed on the resultant structure of FIG. 7. A wet etch solution used for the wet etch process may use a diluted HF solution or a buffed oxide etch (BOE) solution. The degree to recess the recessed buried insulating layer 102a can be determined considering the depth of the source/drain region to be formed in a subsequent process, and can be controlled by controlling a wet etch time appropriately. During the wet etch process, since the sidewalls and the upper surface of the gate conductive layer pattern 121 are surrounded by the gate spacer layer 141 and the hard mask layer pattern 130a respectively, the gate conductive layer pattern 121 is not affected by a wet etch. Further, since the ultra thin film single crystalline silicon layer pattern 103b is disposed on the bottom surface of the gate conductive layer pattern 121, only the buried insulating layer 102 (FIG. 7) is wet-etched by the wet etch.

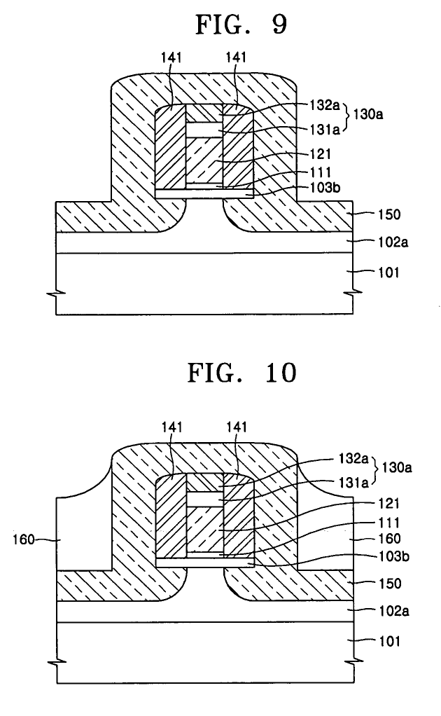

FIGS. 9 through 12 are sectional views illustrating a process of forming a recessed source/drain region in the method of fabricating an SOI MOSFET according to the present invention.

First, as shown in FIG. 9, a polycrystalline silicon layer 150 doped with high concentration impurities as a conductive layer to form a source/drain region is stacked on the overall surface of the resultant structure having the recessed buried insulating layer 102a of FIG. 8. The polycrystalline silicon layer 150 may be deposited using a CVD method, a PVD method, or an atomic layer deposition (ALD) method, and the recessed portion on the recessed buried insulating layer 102a is all filled with the polycrystalline silicon layer 150. Alternatively, the conductive layer may use amorphous silicon or a single crystalline silicon layer formed by an epitaxy growth method. Then, a thermal treatment process is performed to diffuse impurities of the polycrystalline silicon layer 150. The conditions of the thermal treatment process are determined considering the thickness of the gate spacer layer 141, the overlapping degree of the source/drain diffusion region and the polycrystalline silicon layer 150, and the operation characteristics of the device.

Then, as shown in FIG. 10, an etch mask layer pattern 160 is formed to remove the polycrystalline silicon layer 150 (FIG. 9) disposed on the gate stack. The etch mask layer pattern 160 may be formed of a floating oxide layer. Since the floating oxide layer has the characteristics of flowing from the gate stack downward, a spin coating method is used in order to prevent a partial surface portion of the polycrystalline silicon layer 150 on the gate stack from being covered with the floating oxide layer. In cases, the floating oxide layer can be allowed to flow more from the upper portion of the gate stack by controlling thermal treatment conditions. Further, a thermal treatment process of a slightly high temperature can be performed, thereby providing the property of a normal silicon oxide layer. As such, when the etch mask layer pattern 160 is formed of such a floating oxide layer, the floating oxide layer is little left on top of the gate stack, and is formed with a significantly great thickness on the flat region of the polycrystalline silicon layer 150.

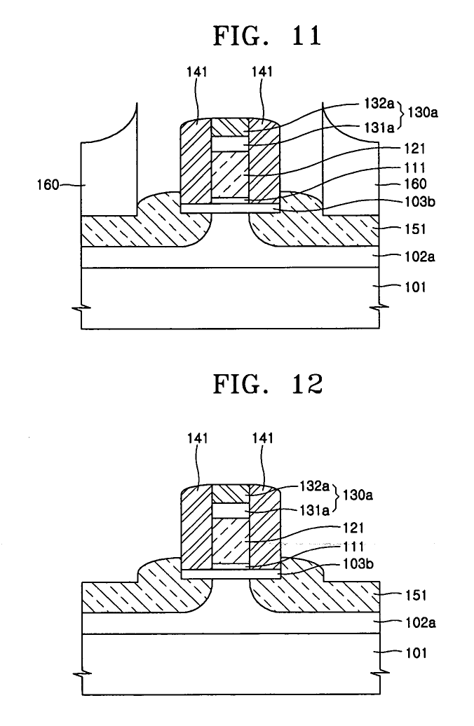

Then, as shown in FIG. 11, an etch process is performed on the polycrystalline silicon layer 150 (FIG. 10) exposed by the etch mask layer pattern 160, thereby forming a recessed source/drain region 151, which is formed of a polycrystalline silicon layer having high concentration impurities diffused therein. The etch process may be performed using an anisotropic etch method. In performing the etch process, an etch time is controlled such that the overlapping portion of the recessed source/drain region 151 and the gate stack is minimized.

Then, as shown in FIG. 12, the etch mask layer pattern 160 is removed. In the case that the etch mask layer pattern 160 is formed of a floating oxide layer, the etch mask layer pattern 160 can be removed performing a wet etch method using a wet etch solution such as a diluted HF solution or a BOE solution. While the wet etch process is performed, since the sidewalls and the upper surface of the gate conductive layer pattern 121 are covered with the gate spacer layer 141 and the hard mask layer pattern 130a respectively, the gate conductive layer pattern 121 is not affected by the wet etch. Further, since the ultra thin film single crystalline silicon layer pattern 103b is disposed on the bottom surface of the gate conductive layer pattern 121, only the etch mask layer pattern 160 (FIG. 11) is wet-etched by the wet etch. After the etch mask layer pattern 160 is removed, the surface of the recessed source/drain region 151 is exposed.

Then, as shown in FIG. 13, a metal silicide layer 170 is formed on the recessed source/drain region 151 by performing a typical silicide process, thereby completing the fabrication of the ultra thin film SOI MOSFET having the recessed source/drain structure according to the present invention.

As described above, according to the ultra thin film SOI MOSFET having the recessed source/drain structure of the present invention, since the inversion layer or the channel is formed inside the ultra thin film single crystalline silicon layer pattern under the gate insulating layer, and the center portion of the recessed buried oxide layer exists thereunder, the inversion layer or the channel cannot be formed deeper. Therefore, even though the source/drain extension region is formed greater in depth, the generation of a short channel effect can be suppressed. As such, since the depth of the inversion layer or the channel is not affected by the thickness of the recessed source/drain region, the thickness of the recessed source/drain region doped with high concentration impurities must be sufficiently increased, thereby reducing a resistance in the recessed source/drain region.

Furthermore, according to the method of fabricating the ultra thin film SOI MOSFET of the present invention, the ultra thin film SOI MOSFET can be easily fabricated to provide the advantages while using existing processes of fabricating bulk semiconductor devices.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An ultra thin film silicon on insulator (SOI) MOS transistor comprising:
a semiconductor substrate;
a buried insulating layer disposed on the semiconductor substrate, and formed recessed except for a center portion thereof;
an ultra thin film single crystalline silicon layer pattern disposed on the recessed buried insulating layer;
a gate stack disposed on the ultra thin film single crystalline silicon layer pattern, and including a gate insulating layer pattern and a gate conductive layer pattern, which are sequentially stacked;
a gate spacer layer disposed on sidewalls of the gate stack; and
a recessed source/drain region disposed on the recessed buried insulating layer, and formed to overlap a bottom surface portion of the ultra thin film single crystalline silicon layer pattern, which does not overlap the center portion of the recessed buried insulating layer.

2. The ultra thin film SOI MOS transistor according to claim 1, wherein the semiconductor substrate, the recessed buried insulating layer, and the ultra thin film single crystalline silicon layer pattern constitute an SOI substrate.

3. The ultra thin film SOI MOS transistor according to claim 1, wherein the recessed buried insulating layer is an oxide layer.

4. The ultra thin film SOI MOS transistor according to claim 1, wherein end portions of the ultra thin film single crystalline silicon layer pattern are formed in a direction normal to sidewalls of the gate spacer layer.

5. The ultra thin film SOI MOS transistor according to claim 1, wherein the recessed source/drain region is a polycrystalline silicon layer doped with high concentration impurities.

6. The ultra thin film SOI MOS transistor according to claim 1, further comprising a hard mask layer pattern disposed on the gate conductive layer pattern.

7. The ultra thin film SOI MOS transistor according to claim 6, wherein the hard mask layer pattern has a structure in which a silicon oxide layer pattern and a silicon nitride layer pattern are sequentially stacked.

8. The ultra thin film SOI MOS transistor according to claim 1, further comprising a metal silicide layer disposed on an exposed surface of the recessed source/drain region.

9. A method of fabricating an ultra thin film SOI MOS transistor comprising:
preparing an SOI substrate formed by sequentially stacking a semiconductor substrate, a buried insulating layer, and a single crystalline silicon layer;
removing the single crystalline silicon layer by a predetermined thickness, thereby forming an ultra thin film single crystalline silicon layer;
forming a gate stack on the ultra thin film single crystalline silicon layer;
forming a gate spacer layer on sidewalls of the gate stack;
removing an exposed portion of the ultra thin film single crystalline silicon layer, being not covered by the gate stack and the gate spacer layer, thereby forming an ultra thin film single crystalline silicon layer pattern disposed below the gate stack and the gate spacer layer;
partially removing the buried insulating layer, thereby forming a recessed buried insulating layer, which is recessed at a rest portion except for a center portion below the ultra thin film single crystalline silicon layer pattern; and
forming a source/drain region on the recessed buried insulating layer.

10. The method according to claim 9, wherein the operation of forming the ultra thin film single crystalline silicon layer comprises:
performing an oxidation process on the single crystalline silicon layer; and
removing an oxide layer formed in an upper portion of the single crystalline silicon layer by the oxidation process.

11. The method according to claim 10, wherein the oxidation process and the oxide layer removing process are performed using a dry oxidation process and a wet etch process respectively.

12. The method according to claim 9, further comprising channel-doping for the ultra thin film single crystalline silicon layer to control a threshold voltage and reduce a short channel effect.

13. The method according to claim 9, wherein the gate stack includes a gate insulating layer pattern and a gate conductive layer pattern, which are sequentially stacked.

14. The method according to claim 13, wherein the gate stack further includes a hard mask layer pattern formed on the gate conductive layer pattern.

15. The method according to claim 14, wherein the gate insulating layer pattern is formed of a silicon thermal oxide layer or a high-k insulating layer, the gate conductive layer pattern is formed of a polycrystalline silicon layer or a metal layer, and the hard mask layer pattern is formed of a silicon oxide layer and a silicon nitride layer.

16. The method according to claim 9, wherein the ultra thin film single crystalline silicon layer pattern is formed by performing an anisotropic etch process on the ultra thin film single crystalline silicon layer exposed by the gate stack and the gate spacer layer.

17. The method according to claim 9, wherein the recessed buried insulating layer is formed by performing a wet etch process on the buried insulating layer.

18. The method according to claim 9, wherein the operation of forming the source/drain region comprises:
forming a conductive layer on an overall surface of the resultant structure having the recessed buried insulating layer;
forming an etch mask layer pattern on the conductive layer to expose an upper surface of the gate stack and the conductive layer around the gate stack;
performing an etch process using the etch mask layer pattern as an etch mask, thereby removing the exposed portion of the conductive layer; and
removing the etch mask layer pattern.

19. The method according to claim 18, wherein the conductive layer is formed of a polycrystalline silicon layer doped with high concentration impurities.

20. The method according to claim 18, wherein the conductive layer is formed of an amorphous silicon layer or a single crystalline silicon layer formed by an epitaxy growth method.
